(19) United States
(12) Patent Application Publication
(10) Pub. No.: US 2012/0194719 A1
(43) Pub. Date: Aug. 2, 2012

(54) IMAGE SENSOR UNITS WITH STACKED IMAGE SENSORS AND IMAGE PROCESSORS

(76) Inventors: Scott Churchwell, Boise, ID (US); Ulrich Boettiger, Boise, ID (US); Swarnal Borthakur, Boise, ID (US); Andrew Perkins, Boise, ID (US); Rick Lake, Meridian, ID (US); Marc Sulfridge, Boise, ID (US)

(21) Appl. No.: 13/080,889

(22) Filed: Apr. 6, 2011

Related U.S. Application Data
(60) Provisional application No. 61/438,580, filed on Feb. 1, 2011.

(51) Int. Cl. H04N 5/335

(52) U.S. Cl. 348/302; 348/E05.091

(57) ABSTRACT

An image sensor unit has stacked imager and processor integrated circuits. The imager may have an image sensor pixel array on its front surface. Processor die may be mounted back-to-back with respective imagers on a wafer. A photodefinable dielectric film may cover the rear surface of the wafer. Metal traces in the photodefinable dielectric and through-silicon vias in each imager may be used to interconnect the processing circuitry on the front surface of a processor to the image sensor pixel array on the front surface of the imager. Openings may be formed in the photo definable dielectric to allow solder balls to form electrical connections with the metal traces. A cavity may be formed in a photo definable dielectric layer or an imager to accommodate the processor. The processor may also be mounted in a cavity in a separate silicon standoff structure before attaching the standoff structure to the imager.

This application claims the benefit of provisional patent application No. 61/438,580, filed Feb. 1, 2011, which is hereby incorporated by reference herein in its entirety.

### BACKGROUND

The present invention relates to imaging devices, and, more particularly, to image sensor units formed using stacked image sensor and processor integrated circuits.

Image sensors are commonly used in electronic devices such as cellular telephones, cameras, and computers to capture images. In a typical arrangement, an electronic device is provided with an image sensor integrated circuit that contains control circuitry for controlling an associated image sensor pixel array. The control circuitry includes row driver circuits for generating control signals such as row select signals. The control signals also include column readout circuitry that converts analog image data signals from data lines in the image sensor pixel array into digital image data. Image processing tasks can sometimes be at least partly performed using image-processing circuits in the image processor integrated circuit. In many situations, however, use of a processor integrated circuit that is separate from the sensor integrated circuit is desirable. For example, separate image processing chips may be used to handle input-output functions and image processing functions that require more processing power than is available on an image sensor integrated circuit.

In many image sensor applications, space is limited. It may also be desirable to minimize the number of integrated circuit components that are used in a given device (e.g., to reduce part count and assembly costs). With conventional arrangements, image sensor integrated circuits and image processing integrated circuits must be separately mounted to a printed circuit board or other substrate.

It would be desirable to be able to provide more compact image sensor arrangements that help reduce part counts and assembly complexity.

### BRIEF DESCRIPTION OF THE DRAWINGS

FIG. 1 is a cross-sectional side view of a partly formed image sensor unit in which an image sensor processor die has been stacked on the back of a wafer of imagers in accordance with an embodiment of the present invention.

FIG. 2 is a cross-sectional side view of the image sensor unit of FIG. 1 following lamination of a layer of photodefinable dielectric over the processor die in accordance with an embodiment of the present invention.

FIG. 3 is a cross-sectional side view of the image sensor unit of FIG. 2 following formation of via holes in the photodefinable dielectric layer in accordance with an embodiment of the present invention.

FIG. 4 is a cross-sectional side view of the image sensor unit of FIG. 3 following formation of a pattern of solder balls on the stacked imager and processor in accordance with an embodiment of the present invention.

FIG. 5 is a cross-sectional side view of an illustrative image sensor unit showing how a photodefinable dielectric layer with a processor cavity may be used in forming an image sensor unit with a stacked imager and processor in accordance with an embodiment of the present invention.

FIG. 6 is a cross-sectional side view of an illustrative partially formed image sensor unit being formed using a cavity in the rear surface of an imager in accordance with an embodiment of the present invention.

FIG. 7 is a cross-sectional side view of an illustrative image sensor unit following attachment of a processor die within an image sensor cavity formed in a wafer of image sensors in accordance with an embodiment of the present invention.

FIG. 8 is a cross-sectional side view of an illustrative arrangement for forming an image sensor unit using a cavity formed in the rear surface of an imager in accordance with an embodiment of the present invention.

FIG. 9 is a cross-sectional side view of an image sensor unit during assembly using an imager backside cavity and a photodefinable dielectric that has been exposed using both full and partial exposure regions in accordance with an embodiment of the present invention.

FIG. 10 is a cross-sectional side view of a silicon standoff structure that has a cavity in which a processor die has been mounted in accordance with an embodiment of the present invention.

FIG. 11 is a cross-sectional side view of a silicon standoff structure of the type shown in FIG. 10 following stacking of the standoff and processor with a corresponding imager in accordance with an embodiment of the present invention.

### DETAILED DESCRIPTION

Digital camera modules are widely used in electronic devices such as digital cameras, computers, cellular telephones, and other electronic devices. These electronic devices may include image sensors that gather incoming light to capture an image. The image sensors may include arrays of image pixels. The pixels in the image sensors may include photosensitive elements such as photodiodes that convert the incoming light into digital data. Image sensors may have any number of pixels. An image sensor may, for example, have hundreds, thousands, or millions of pixels (e.g., megapixels).

An image sensor integrated circuit that includes an image sensor pixel array and associated control circuitry is sometimes referred to as an imager. The imager may contain control circuits that control the transistors associated with the array of image pixels. The control circuits may include circuitry to convert image data signals from the array of image pixels into digital signals. Additional imaging processing operations on the image data can be performed using processing circuitry within the imager die or on a separate image processor integrated circuit. Such separate image processor integrated circuits are sometimes referred to herein as processors or image processors.

To save space and simplify assembly by a manufacturer of a camera or other electronic device in which imaging capabilities are desired, it may be desirable to stack a processor and an imager to form a preassembled image sensor unit. An image sensor unit that is formed in this way has the image sensing capabilities of the imager and the processing capabilities of the processor in a single component.

When forming an integrated sensor unit of this type, it is generally desirable to form a robust stack of integrated circuits without undue process complexity. With one suitable arrangement, which is sometimes described herein as an example, one or more layers of photodefinable dielectric such as dry film resist are laminated to the imager and processor. With dry film photoresist (resist) techniques, a flexible sheet of dry photoresist is used as the photodefinable dielectric. A photodefinable dielectric of this sypte may be provided with a removable cover sheet to facilitate handling. Following vacuum lamination of the photodefinable dielectric, the cover sheet may be removed. The photodefinable dielectric may then be patterned using photolithographic techniques. For example, if the photodefinable dielectric is a negative resist, the photodefinable dielectric can be exposed to ultraviolet light in regions of the film where it is desired to retain the resist. Subsequent development of the photodefinable dielectric can be used to remove the unexposed areas. The use of photodefinable dielectrics such as dry film resists are sometimes described herein as an example, but photodefinable dielectrics may also be formed from a dielectric coating such as a resist that is deposited by spinning, spraying, or dipping.

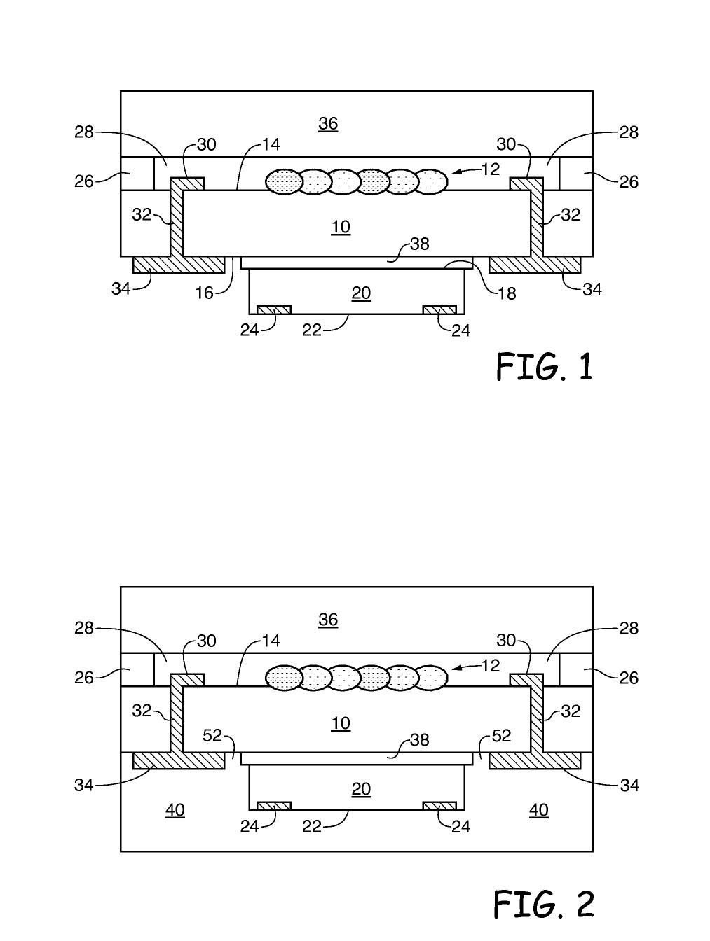

A cross-sectional side view of an illustrative partly completed image sensor unit formed from a stacked imager and processor is shown in FIG. 1. In this example, the image sensor unit includes two integrated circuits stacked back to back. If desired, more than two integrated circuits may be combined to form a stacked unit. For example, an imager, a memory chip, and a processor may be combined using a stacking arrangement. Integrated circuits may be stacked on top of each other and/or side-by-side. Stacked integrated circuits may include memory devices, application-specific integrated circuits, digital signal processing units, microprocessors, image sensors, and other integrated circuits. The arrangement of FIG. 1 in which an image sensor unit is formed by stacking an imager and a processor is merely illustrative.

At the stage of the image sensor unit fabrication process that is shown in FIG. 1, a wafer of imagers 10 has been formed using semiconductor processing techniques. As shown by front-side image sensor components 12, each imager may include components such as an array of microlenses, a color filter array, and a corresponding array of image sensor pixels. Each image sensor pixel may include a photosensitive element such as a photodiode and associated control circuitry (e.g., a transfer gate, a source-follower transistor, a row select transistor, etc.). Control circuitry such as row drivers and column readout circuitry may also be included in front-side sensor components 12. The image sensor pixel array in components 12 may include hundreds or thousands of rows and columns of image pixels (as an example).

Multiple imagers 10 may be formed in the wafer (e.g., in rows and columns). Each imager has an upper surface 14, which is sometimes referred to as the front side of the imager. During operation, image light is focused onto front surface 14 by a lens. The lens and the image sensor unit made up of imager 10 and processor 20 may be mounted in a camera module. The camera module may be used in an electronic device such as a camera, computer, cellular telephone, or other equipment.

Through-silicon vias (sometimes referred to as through-wafer vias) such as vias 32 may be used to connect a pattern of front surface traces 30 to patterned traces 34 on back surface 16 of the wafer. Patterned traces 30 form front side interconnects and are interconnected to the image pixel array and other circuitry within components 12. Patterned traces 34 form imager contact pads that may be used to interconnect the circuitry of each imager to the circuitry of a corresponding processor. Because traces 34 can be associated with pads that have a different layout than through-silicon vias 32, traces 34 are sometimes referred to as forming a redistribution layer.

After the array of imagers 10 has been formed on the wafer, a layer of glass such as glass layer 36 may be attached to the front side of the wafer using stand-off adhesive 26. If desired, a temporary protective cover formed from a silicon wafer may be attached to the front surface of the wafer instead of glass layer 36. Attachment of glass layer 36 (or other protective layer) to the front surface of the wafer gives rise to gap 28 above front side components 12 and serves to strengthen the wafer for processing. The glass layer may remain in place following fabrication operations (i.e., after the wafer has been diced into individual image sensor units).

Following formation of the wafer of imagers and attachment of glass layer 36, a pick and place tool or other assembly tool may be used to attach a processor such as processor 20 to the rear surface of each imager 10. The processor thickness may be pre-determined according to the final thickness desired. The processor wafer may then be thinned to the desired thickness. A layer of adhesive such as adhesive 38 may be used to attach each processor 20. Adhesive 38 may be, for example, epoxy or die attach film.

Each processor 20 may have a front surface on which processing circuitry is formed such as front surface 22 and may have a rear surface such as rear surface 18. The front side circuitry has associated contact pads 24 (sometimes referred to as bond pads). If desired, some of the front surface traces on processor 20 may be formed as part of a redistribution layer. Use of a separate redistribution layer may be avoided in configurations in which the patterned traces on the front surface of processor 20 include appropriately patterned contact pads. With the illustrative mounting arrangement shown in FIG. 1, processor 20 is mounted in a back-to-back configuration, so that rear surface 18 of processor 20 faces the rear surface 16 of imager 10. This exposes processor contact pads 24. There may be, for example, 10-40 imager contact pads 34 and tens or hundreds of processor contact pads 24.

Following attachment of the processors to the rear surface of the imagers in the wafer, the rear surface of the wafer may be coated with a photodefinable dielectric layer. Photodefinable dielectrics such as dry film photoresist (resist) may be patterned using photolithographic techniques, but, unlike conventional liquid resists that are typically applied by spraying or spinning, photodefinable dielectrics such as dry film resist may be applied using vacuum lamination tools. There is typically a removable protective cover film on a photodefinable dielectric layer of this type that is removed following lamination in the lamination tool. The protective cover film can be removed after lamination (before photo exposure) or after photo exposure. The photodefinable dielectric may be angled with respect to the rear surface of the wafer during application of the photodefinable dielectric to avoid formation of trapped air bubbles. The lamination tool may compress the photodefinable dielectric film and processor die at an elevated temperature to help the photodefinable dielectric to flow and fill gaps.

FIG. 2 is a cross-sectional side view of the wafer of stacked imagers and processors of FIG. 1 following lamination operations to attach photodefinable dielectric layer 40 to the rear surface of the wafer. The thickness of photodefinable dielectric 40 is preferably sufficiently large to cover processor 20. If, as an example, processor 20 is 40 microns thick, photodefinable dielectric 40 may have a thickness of 50 microns (as an example). In other configurations, photodefinable dielectric 40 may have other thicknesses (e.g., a thickness of about 12 microns in configurations in which it is not desired to cover processor 20 or a thickness of 100 microns or other thicknesses above or below 50 microns).

During the vacuum lamination process that is used in attaching photodefinable dielectric 40 to the rear surface of the wafer, the vacuum and temperature in the vacuum lamination tool cause photodefinable dielectric 40 to fill gaps within surface features on the rear surface of the wafer, such as gaps 52. The vacuum lamination tool (or, if desired, an optional wafer bonding tool) may heat and compress and photodefinable dielectric layers against the wafer sufficiently to planarize the lower surface of the wafer and the stacked processors and facilitate the filling of gaps.

After photodefinable dielectric 40 has been attached to the rear surface of the wafer of imagers 10 and associated processors 22, photodefinable dielectric 40 may be patterned using photolithography. If, for example, photodefinable dielectric 40 is a negative resist, a mask and ultraviolet light source may be used to expose photodefinable dielectric 40 in areas that are not to be removed during subsequent development in a liquid developer. Areas that are to be removed by the developer may be left unexposed. The portions of photodefinable dielectric 40 that are to be removed may correspond to vias through photodefinable dielectric 40.

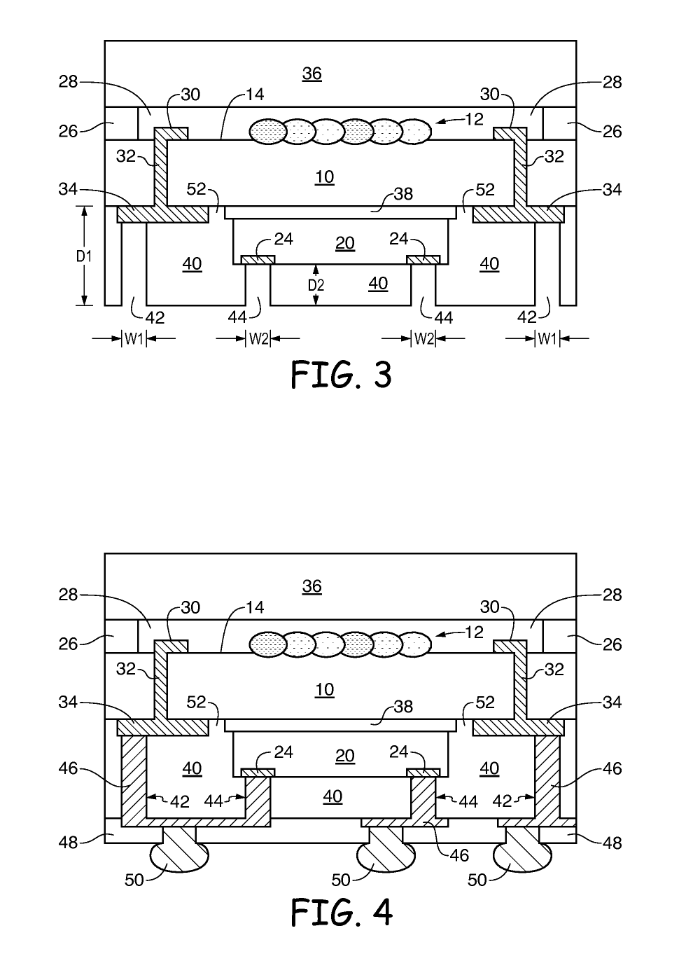

FIG. 3 is a cross-sectional side view of the wafer of imagers and attached processors following development of the exposed photodefinable dielectric 40 to form vias such as vias 42 and vias 44. As shown in FIG. 3, vias 42 and 44 need not have the same size. For example, vias 42, which extend from the rear surface of photodefinable dielectric 40 to rear-surface imager traces 34 may have a depth D1 that is larger than depth D2 of shallower vias 44, which extend from the lower surface of the photodefinable dielectric 40 to front-surface processor traces 44. The lateral dimension (width) of vias 42 and 44 also need not be the same. For example, vias 44 may have a diameter of about 100 microns (as an example), whereas vias 44 may have a width W2 of about 30 microns or less (as an example).

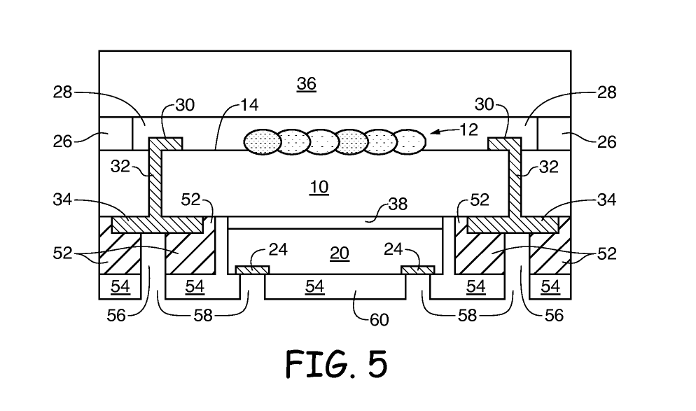

Following formation of vias, metal 46 may be used to form interconnects through vias 42 and 44, as shown in FIG. 4. Metal 46 may be formed by forming one or more layers of metal in the bare vias of FIG. 3. With one suitable arrangement, an adhesion layer of about 150 angstroms in thickness (e.g., a layer of titanium or tantalum) may be deposited onto the surface of vias 42 and 44, followed by deposition of a seed layer (e.g., a layer of copper or other metal about 2000-6000 angstroms thick that may serve to initiate subsequent copper plating operations). The seed layer may be patterned using photolithography (e.g., by using resist to protect portions of the seed layer in the vias and by etching away unwanted portions of the seed layer). The adhesion and seed layers may be deposited by physical vapor deposition (e.g., sputtering). The thickness of the copper layer may then be increased (e.g., to about 1-3 microns) by electrochemical deposition (e.g., electroplating). After electroplating the copper, Ni and Pd may be electroplated on the copper to serve as under bump metallization (UBM) for solder balls. After electroplating of the Cu, Ni, and Pd is complete, photoresist may be stripped. A wet etch may be used to etch the Cu seed and a dry etch may be used on the adhesion/barrier layer. The photodefinable dielectric layer 40 of FIG. 4 serves as an interlayer dielectric layer. Patterned metal traces 46 on the lower surface of photodefinable dielectric 40 and in vias 42 and 44 and traces 34 and 32 on imager 10 electrically interconnect imager circuitry such as components 12 and traces 30 to circuitry on front surface 22 of processor 20 such as traces 24.

As shown in FIG. 4, following formation of traces 46, an additional layer of photodefinable dielectric material (photodefinable dielectric layer 48) may be laminated to the lower surface of the photodefinable dielectric. Photodefinable dielectric layer 48 may have a thickness of about 12 microns (as an example) Vias in photodefinable dielectric layer 48 may then be formed to accommodate formation of solder balls 50 that are connected to traces 46. Solder balls 50 may be used to form electrical connections between external circuitry and processor pads 24 and/or imager pads 34. Solder for solder balls 50 may be deposited by screen printing a solder paste in a desired pattern and applying heat to reflow the solder.

After a wafer of image sensor modules has been formed using stacked imager and processor arrangements of the type shown in FIG. 4, the wafer may be divided (e.g., diced) into individual image sensor units each containing an imager 20 and a stacked processor 20. Customers need not be concerned with the chip scale packaging processes that were used to form the image sensor units and may install the image sensor units in products as with conventional integrated circuit die. The stacking process of FIGS. 1-4 does not require the formation of through-silicon vias in processor 20, simplifying processing. Additional metal layers (e.g., for additional interconnects) may be formed by adding additional layers of photodefinable dielectric.

If desired, two photodefinable dielectric layers may be formed on the rear surface of the wafer in place of photodefinable dielectric 40. This type of approach is shown in FIG. 5. With the approach of FIG. 5, a first photodefinable dielectric layer (layer 52) is laminated to the rear surface of the wafer before attachment of image processor die 20. A cavity that is sufficiently large to accommodate processor 20 may then be formed in layer 52 (e.g., using photolithography—exposing and developing layer 52). At the same time that the cavity for processor 20 is being formed, vias 56 in layer 52 may be formed in alignment with imager traces 34. Processor 20 may be attached with adhesive 38 to the rear surface of imager 10 within the cavity that has been formed. The thickness of photodefinable dielectric 52 may be selected to be substantially equal to the thickness of processor 20. For example, if processor 20 has a thickness of about 50 microns, photodefinable dielectric 52 may also have a thickness of about 50 microns. Arrangements in which photodefinable dielectric 52 has a thickness of less than the processor thickness (and in which the dielectric layer is thickened through subsequent photodefinable dielectric lamination steps) may also be used.

Following patterning of the vias 56 in photodefinable dielectric 52 and attachment of processor 20 to imager 10, a second layer of photodefinable dielectric (photodefinable dielectric layer 54) may be laminated to the lower surface of photodefinable dielectric 52. Photodefinable dielectric layer 54 may, if desired, have a relatively small thickness (e.g., about 12 microns). During vacuum lamination of photodefinable dielectric 54 to photodefinable dielectric 52, some of photodefinable dielectric layer 54 may fill vias 56. During subsequent photolithographic patterning, vias 58 may be formed in photodefinable dielectric layer 54. The uniform thickness of photodefinable dielectric 54 facilitates via formation, because ultraviolet light that is applied to photodefinable dielectric 54 as part of the photolithography process tends to be evenly distributed throughout the uniform thickness of photodefinable dielectric 54. In the bottom of vias 58, unexposed photodefinable dielectric 54 can be removed during photoresist development operations, because this material will not have been exposed during the ultraviolet light exposure used in patterning vias 58. Vias 58 may be formed with slightly larger widths than vias 56 to facilitate subsequent metal deposition operations. Following metallization of vias 56 and 58 with metal 46 and attachment of solder balls 50, the stacked imager and processor wafer may be divided into individual image sensor units and installed in a camera module for use in a camera or other electronic equipment.

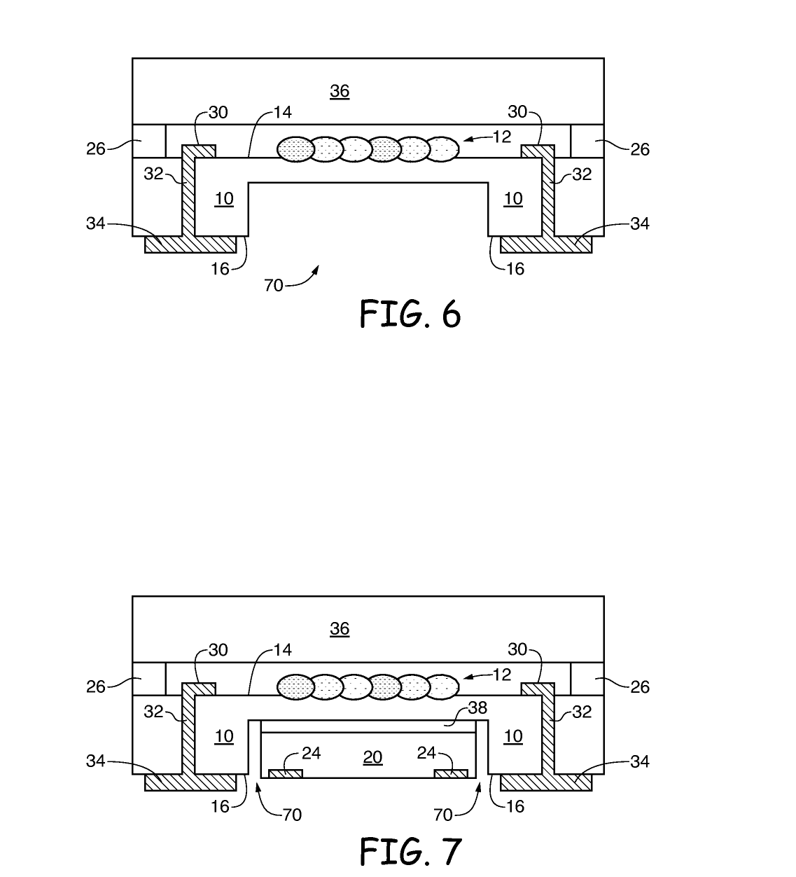

Cavities may be formed in the rear surface of a wafer of integrated circuits to accommodate attachment of die such as processors, memory circuits, or other chips. For example, a wafer of imagers 10 may be provided with cavities such as cavity 70 of FIG. 6. Each imager 10 may, for example, be provided with a cavity 70 that has a depth that is substantially equal to the thickness of a corresponding processor (as an example). Cavity 70 may be formed using a dry silicon etch process that forms relatively straight sidewalls. If desired, cavity 70 may have a depth that is shallower than processor 20 and subsequently deposited layers of photodefinable dielectric may be used to accommodate the resulting height difference between the rear of processor 20 and the lower surface of the photodefinable dielectric.

After cavities such as cavity 70 have been formed in the rear surface of the imaging wafer (i.e., through the rear surface 16 of each imager 10), corresponding processors such as processor 20 of FIG. 7 may each be mounted within a respective cavity using adhesive 38 (e.g., epoxy or die attach film).

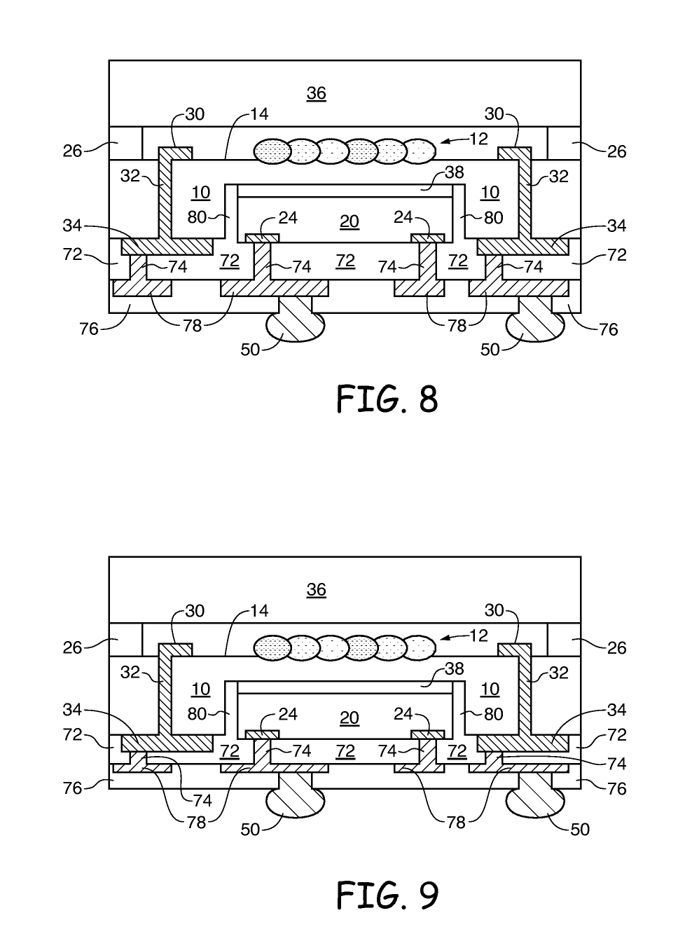

FIG. 8 is a cross-sectional side view of the image sensor unit of FIG. 7 following attachment and patterning of two layers of photodefinable dielectric. Initially, photodefinable dielectric layer 72 is vacuum laminated to the lower surface of the wafer of imagers 10, filling gaps such as gap 80. Vias may be formed and filled with metal traces 74 using a metal deposition process of the type described in connection with metal 46 of FIGS. 1-4. Metal traces 78 (e.g., a redistribution layer) may be formed on the surface of layer 72 in electrical contact with appropriate vias (traces 74). The vias may have substantially similar depths, but different widths or may have substantially similar depths and widths (i.e., equal depths and widths). For example, the width of the vias used in connecting metal 78 to metal 34 may be larger than the width of the vias used in connecting metal 78 to processor contacts 24. After forming patterned metal traces 74 and 78, additional photodefinable dielectric layer 76 may be laminated to the lower surface of the wafer. Films 72 and 76 may have thicknesses of about 12 microns (as an example).

Following attachment of layer 76, openings may be formed in layer 76 over portions of traces 78 on which solder balls are to be formed. Solder balls 50 may then be formed and the wafer diced into individual image sensor units, each including a stacked image sensor 10 and processor 20. The metal interconnects in the through-silicon vias in imager 10 and the metal interconnects in the interconnect dielectric formed by layers 72 and 76 form electrical pathways that interconnect processor contacts 24, imager contacts 30, and image sensor unit solder balls 50.

If desired, the amount of photolithography involved in patterning the photodefinable dielectric layers may be reduced by using a double-exposure photolithography technique to open vias and form metal layers 74 and 78. In the arrangement of FIG. 8, vias 74 are formed in layer 72 by exposing and developing layer 72 and depositing and patterning metal 74. Following lamination of photodefinable dielectric layer 76, photodefinable dielectric layer 76 is exposed and developed to form openings for solder balls 50.

With an arrangement of the type shown in FIG. 9, photodefinable dielectric 72 is exposed to ultraviolet light and developed as with the arrangement of FIG. 8. However, unlike the arrangement of FIG. 8, photodefinable dielectric 72 of FIG. 9 is only partly exposed in some portions and is exposed fully in other portions. This allows formation of shallow regions for accommodating interconnects such as metal traces 78 and deep portions for accommodating vias 74. The type of dielectric used for photodefinable dielectric 72 of FIG. 9 may be, for example, positive photoresist. With this type of approach, layer 72 may be only partially exposed in the portions of layer 72 corresponding to metal traces 76 and fully exposed in the portions of layer 72 corresponding to via metal 74. After photodefinable dielectric 72 has been exposed to ultraviolet light in this way, photodefinable dielectric 72 may be developed. The portions of layer 72 that were fully exposed will be removed completely (i.e., the entire thickness of layer 72 will have been exposed to ultraviolet light and will be removed to form vias for contacting metal 34). The portions of layer 72 that were partially exposed (i.e., only shallowly exposed) will only be partly removed (i.e., the outermost portion will be removed during photoresist development but the deeper portions will remain). The partially removed portions will therefore form shallow recesses for receiving metal 76 (e.g., redistribution layer metal and contact pads for solder balls 50).

After the deep and shallow features have been formed in photodefinable dielectric 72 by developing photodefinable dielectric 72, metal layers 74 and 76 may be formed in a single sequence of metal deposition steps (e.g., using patterned adhesion and seed layers followed by subsequent electrochemical deposition such as electroplating). Layers 74 and 76 may therefore be formed at the same time as part of the same deposition process. A chemical mechanical polishing step may be performed after plating operations have been performed to thicken the metal to polish off protruding surface features. Because processor 20 is embedded at least partly within the cavity in the rear surface of imager 10, the total thickness of the image sensor unit may be minimized.

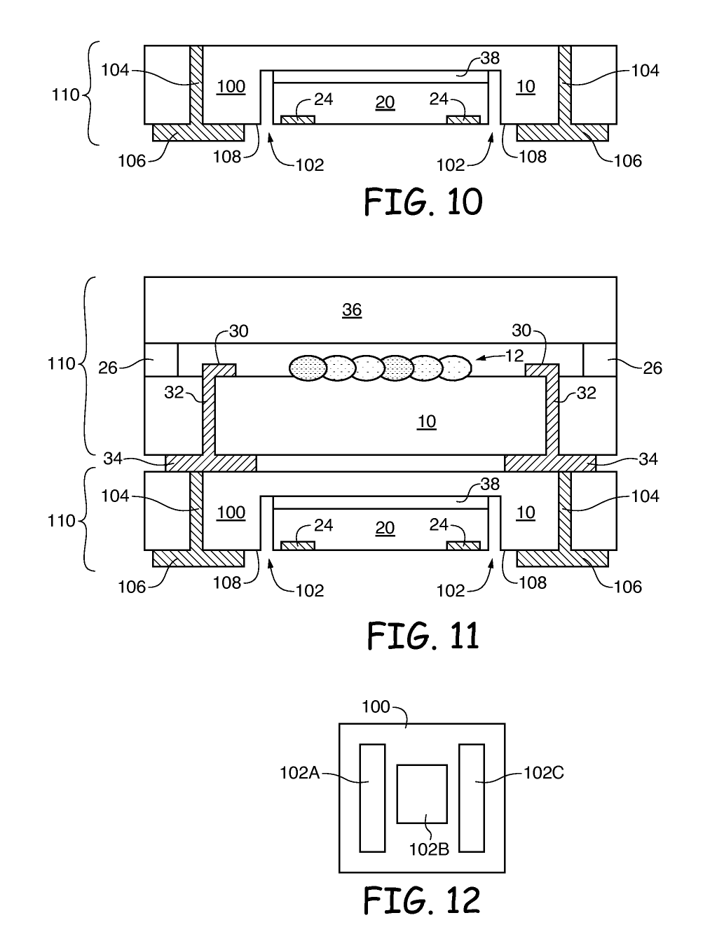

If desired, a silicon structure may be used in mounting processors to imagers in image sensor units. An arrangement of this type is shown in FIGS. 10 and 11. As shown in FIG. 10, silicon standoff wafer 100 may be provided with cavities such as cavity 102. Cavities 102 may be etched into rear surface 108 of silicon standoff structures such as standoff structure 100 using dry etching (as an example). Through-silicon vias 104 may be formed through each silicon standoff structure 100 on the wafer (e.g., by dry etching) and may be connected to metal traces 106 on rear surface 108 of each silicon standoff structure 100.

Following formation of cavities such as cavity 102, metal traces 104 in through-silicon vias, and metal traces 106 (e.g., contact pads in a redistribution layer), a pick and place tool or other suitable assembly equipment may be used to mount processors such as processor 20 within each cavity using adhesive 38, thereby forming preassembled standoff wafer 110.

Preassembled standoff wafer 110 may then be mounted to a wafer of imagers 10 that have been bonded to a glass layer 36 to form preassembled imager wafer structure 112, as shown in FIG. 11. When mounted in this way, the conductive traces in structure 110 may mate with corresponding conductive traces in structure 112. After structures 110 and 112 have been attached as shown in FIG. 11, a photodefinable dielectric may be laminated to the surface of structure 110 and patterned to open up holes for solder bond balls (as an example). The structures may then be diced into individual image sensor units.

As shown in FIG. 12, each standoff structure wafer may have multiple cavities such as cavities 102A, 102B, and 102C associated with each sensor. Cavities 102A, 102B, and 102C may each be configured to receive a respective integrated circuit die (e.g., a processor, a memory device, etc.).

Various embodiments have been described illustrating image sensor units that are formed using stacked integrated circuit die. Image sensor integrated circuits may be formed in rows and columns on an image sensor wafer. A respective processor may be stacked with each one of the image sensors. A back-to-back mounting arrangement may be used in which each processor is mounted with its rear surface facing the rear surface of a corresponding imager. Layers of photodefinable dielectric may be used in assembling a stacked processor and imager.

An imager may each be provided with through-silicon vias to allow front surface circuitry to mate with a pattern of metal traces on the rear surface of the imager. The processor may have pads that are connected to the through-silicon vias of the imager using vias and other interconnects formed in the photodefinable dielectric layers. Solder balls may form connections to the metal traces in the photodefinable dielectric.

A cavity may be formed in the rear surface of an imager to accommodate a processor. A processor may also be mounted in a cavity in a silicon standoff structure. The silicon standoff structure may then be mounted to an imager.

The foregoing is merely illustrative of the principles of this invention which can be practiced in other embodiments.

What is claimed is:

1. An image sensor unit, comprising:
an imager integrated circuit that contains an array of image pixels, wherein the imager integrated circuit has a front surface on which the array of image pixels is formed, a rear surface, and through-silicon vias that pass between the front and rear surfaces; and
a processor integrated circuit having a front surface that includes processor circuitry and a rear surface that is attached to the rear surface of the imager integrated circuit using adhesive.

2. The image sensor unit defined in claim 1 further comprising:
a photodefinable dielectric layer that covers the front surface of the processor integrated circuit.

3. The image sensor unit defined in claim 2 further comprising:
contact pads on the front surface of the processor integrated circuit;
contact pads on the rear surface of the imager integrated circuit that are electrically coupled to the array of image pixels using the through-silicon vias; and
metal traces in the photodefinable dielectric layer that connect the contact pads on the front surface of the processor integrated circuit to the contact pads on the rear surface of the imager integrated circuit.

4. The image sensor unit defined in claim 3 further comprising at least one metal structure on the front surface of the imager integrated circuit that is coupled between the image sensor pixels and the through-silicon vias.

5. The image sensor unit defined in claim 3 further comprising an additional photodefinable dielectric layer that covers at least some of the metal traces;
openings in the additional photodefinable dielectric layer; and
solder balls that are connected to the metal traces through the openings.

6. The image sensor unit defined in claim 1 further comprising:
a photodefinable dielectric layer having a cavity, wherein the processor integrated circuit is mounted within the cavity; and
an additional photodefinable dielectric layer that covers the front surface of the processor integrated circuit, wherein the additional photodefinable dielectric layer comprises openings through which metal connects to contact pads on the front surface of the processor integrated circuit.

7. The image sensor unit defined in claim 1 further comprising a photodefinable dielectric layer that covers the front surface of the processor integrated circuit, wherein the photodefinable dielectric contains at least a first via that forms an electrical contact to the imager integrated circuit and at least a second via that forms an electrical contact to the processor integrated circuit, wherein the first via has a first depth and a first width, and wherein the second via has a second depth and a second width, and wherein at least the first and second widths are equal.

8. The image sensor unit defined in claim 1 further comprising a photodefinable dielectric layer that covers the front surface of the processor integrated circuit, wherein the photodefinable dielectric contains at least a first via that forms an electrical contact to the imager integrated circuit and at least a second via that forms an electrical contact to the processor integrated circuit, wherein the first via has a first depth and a first width, and wherein the second via has a second depth and a second width, and wherein at least the first and second depths are equal.

9. The image sensor defined in claim 1 further comprising:
a photodefinable dielectric layer that covers the front surface of the processor integrated circuit, wherein the photodefinable dielectric contains at least a first via that forms an electrical contact to the imager integrated circuit and at least a second via that forms an electrical contact to the processor integrated circuit, wherein the first via has a first depth and a first width, and wherein the second via has a second depth that is different than the first depth and a second width that is different than the first width.

10. An image sensor unit, comprising:
an imager integrated circuit having a front surface that includes an image sensor pixel array and a rear surface that includes a cavity; and
a processor integrated circuit mounted at least partially within the cavity.

11. The image sensor unit defined in claim 10 wherein the imager integrated circuit includes through-silicon vias that pass from the front surface of the imager integrated circuit to the rear surface of the imager integrated circuit.

12. The image sensor unit defined in claim 11, wherein the through-silicon vias are coupled to the image sensor pixel array and are connected to pads on the rear surface of the image sensor integrated circuit.

13. The image sensor unit defined in claim 12 wherein the processor integrated circuit comprises a front surface with contact pads and a rear surface, and wherein the rear surface of the processor integrated circuit is mounted to the imager integrated circuit with adhesive.

14. The image sensor unit defined in claim 13 further comprising a photodefinable dielectric layer that covers that front surface of the processor integrated circuit and that covers at least part of the rear surface of the imager integrated circuit.

15. The image sensor unit defined in claim 14 further comprising metal traces in the photodefinable dielectric layer that are electrically coupled to the through-silicon vias and the contact pads on the front surface of the processor integrated circuit.

16. The image sensor unit defined in claim 15 further comprising:
an additional photodefinable dielectric layer, wherein the additional photodefinable dielectric layer has openings; and
solder balls coupled to the metal traces in the photodefinable dielectric layer through the openings in the additional photodefinable dielectric layer.

17. The image sensor unit defined in claim 15 wherein the photodefinable dielectric layer comprises shallow openings and deep openings that receive the metal traces and wherein the deep openings include portions of the metal traces that connect to the contact pads on the front surface of the processor integrated circuit.

18. An image sensor unit, comprising:
a silicon standoff structure having a cavity;
a processor integrated circuit mounted in the cavity; and
an image sensor integrated circuit having a front surface that includes an image sensor pixel array and having a rear surface to which the silicon standoff structure is mounted.

19. The image sensor unit defined in claim 18 wherein the processor integrated circuit has a front surface that includes contact pads and includes a rear surface and wherein the rear surface of the processor integrated circuit is attached to the silicon standoff structure in the cavity using adhesive

20. The image sensor unit defined in claim 19 further comprising:
through-silicon vias in the image sensor integrated circuit that pass between the front surface and the rear surface.
